(19) United States
(12) Patent Application Publication
(10) Pub. No.: US 2023/0071249 A1
(43) Pub. Date: Mar. 9, 2023

(54) ETCHING AND PLASMA UNIFORMITY CONTROL USING MAGNETICS

(71) Applicant: Lam Research Corporation, Fremont, CA (US)

(72) Inventors: Scott Briggs, Menlo Park, CA (US); Pratik Mankidy, Fremont, CA (US); John P. Holland, San Jose, CA (US); Andrew D. Bailey, III, Milpitas, CA (US)

(21) Appl. No.: 17/795,843

(22) PCT Filed: Jan. 29, 2021
(86) PCT No.: PCT/US2021/015805

§ 371 Date: Jul. 27, 2022

Related U.S. Application Data
(60) Provisional application No. 62/968,044, filed on Jan. 30, 2020.

(51) Int. Cl. H01J 37/32; G01R 33/02

(52) U.S. Cl. CPC H01J 37/3266; H01J 37/32091; H01J 37/3299; G01R 33/02; H01J 2237/24564; H01J 2237/0264; H01J 2237/3343; H01L 21/6831

(57) ABSTRACT

Methods, systems, apparatuses, and computer programs are presented for controlling etch rate and plasma uniformity using magnetic fields. A semiconductor substrate processing apparatus includes a vacuum chamber including a processing zone for processing a substrate using capacitively coupled plasma (CCP). The apparatus further includes a magnetic field sensor configured to detect a signal representing a residual magnetic field associated with the vacuum chamber. At least one magnetic field source is configured to generate one or more supplemental magnetic fields through the processing zone of the vacuum chamber. A magnetic field controller is coupled to the magnetic field sensor and the at least one magnetic field source. The magnetic field controller is configured to adjust at least one characteristic of the one or more supplemental magnetic fields, causing the one or more supplemental magnetic fields to reduce the residual magnetic field to a pre-determined value.

### CLAIM OF PRIORITY

This application is a U.S. National Stage Filing under 35 U.S.C. 371 from International Application No. PCT/US2021/015805, filed on Jan. 29, 2021, and published as WO 2021/155218 A1 on Aug. 5, 2021, which claims the benefit of priority to U.S. Patent Application Ser. No. 62/968,044, filed on Jan. 30, 2020, each of which is incorporated by reference herein in its entirety.

### TECHNICAL FIELD

The subject matter disclosed herein generally relates to methods, systems, and machine-readable storage media for controlling etch rate and plasma uniformity using magnetic fields in a capacitively coupled plasma (CCP) used in semiconductor manufacturing.

### BACKGROUND

Semiconductor substrate processing apparatuses are used to process semiconductor substrates by techniques including etching, physical vapor deposition (PVD), chemical vapor deposition (CVD), plasma-enhanced chemical vapor deposition (PECVD), atomic layer deposition (ALD), plasma-enhanced atomic layer deposition (PEALD), pulsed deposition layer (PDL), plasma-enhanced pulsed deposition layer (PEPDL), and resist removal. One type of semiconductor substrate processing apparatus is a plasma processing apparatus using CCP that includes a vacuum chamber containing upper and lower electrodes, where a radio frequency (RF) power is applied between the electrodes to excite a process gas into plasma for processing semiconductor substrates in the reaction chamber.

In semiconductor substrate processing apparatuses, such as the CCP-based vacuum chambers for manufacturing substrates, etch uniformity and ion tilt at the substrate center are influenced by plasma density uniformity, which has shown sensitivity to weak magnetic fields. For example, plasma density uniformity in CCP-based vacuum chambers can be influenced by magnetic fields associated with magnetized chamber components (which may be associated with a magnetic field strength of 5-10 Gauss) as well as other external magnetic fields including the Earth's magnetic field (which may have a magnetic field strength of 0.25-0.65 Gauss) or other ambient magnetic fields (which may have a magnetic field strength of 0.4-0.5 Gauss).

Currently, controlling plasma uniformity, particularly at the center of the substrate, is a challenge. Changing the dimension of the ground electrode within the chamber, gas and chemistry flows or the frequency content of delivered radio frequency (RF) are the main factors used to control uniformity. However, the magnetization of processing chamber components as well as exposure to external magnetic fields influences plasma density uniformity and varies greatly from chamber to chamber within a manufacturing location, as well as between chambers at different manufacturing locations. The present disclosure seeks to address, amongst other things, the drawbacks associated with conventional techniques for plasma density uniformity.

The background description provided herein is to generally present the context of the disclosure. It should be noted that the information described in this section is presented to provide the skilled artisan some context for the following disclosed subject matter and should not be considered as admitted prior art. More specifically, work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods, systems, and computer programs are presented for controlling etch rate and plasma uniformity using magnetic fields in CCP used in semiconductor manufacturing. One general aspect includes a semiconductor substrate processing apparatus. The apparatus includes a vacuum chamber with a processing zone for processing a substrate using capacitively coupled plasma (CCP). The apparatus further includes a magnetic field sensor configured to detect a signal representing a residual magnetic field associated with the vacuum chamber. The magnetic field sensor may be within the vacuum chamber or outside the vacuum chamber (e.g., within a shielding surrounding the vacuum chamber or outside such shielding). The residual magnetic field may be a field detected inside the vacuum chamber or outside the vacuum chamber (e.g., within a shielding structure surrounding the vacuum chamber or outside the shielding structure). The apparatus further includes at least one magnetic field source configured to generate one or more supplemental magnetic fields through the processing zone of the vacuum chamber. The apparatus further includes a magnetic field controller coupled to the magnetic field sensor and the at least one magnetic field source. The magnetic field controller is configured to adjust at least one characteristic of the one or more supplemental magnetic fields, causing the one or more supplemental magnetic fields to reduce the residual magnetic field to a pre-determined value.

One general aspect includes a method for controlling etch rate and plasma uniformity using magnetic fields in CCP. The method includes detecting a residual magnetic field associated with a processing zone of a vacuum chamber, the processing zone for processing a semiconductor substrate using the CCP. The residual magnetic field may be a field detected inside the vacuum chamber or outside the vacuum chamber (e.g., within a shielding structure surrounding the vacuum chamber or outside the shielding structure). The method further includes determining a magnitude of the residual magnetic field. The method further includes generating using at least one magnetic field source, one or more supplemental magnetic fields through the processing zone of the vacuum chamber based on the determined magnitude of the residual magnetic field.

One general aspect includes a non-transitory machine-readable storage medium including instructions that, when executed by a machine, cause the machine to perform operations including detecting a residual magnetic field associated with a processing zone of a vacuum chamber. The residual magnetic field may be a field detected inside the vacuum chamber or outside the vacuum chamber (e.g., within a shielding structure surrounding the vacuum chamber or outside the shielding structure). The processing zone may be used for processing a semiconductor substrate using capacitively coupled plasma (CCP). A magnitude of the residual magnetic field may be determined. One or more supplemental magnetic fields may be generated through the processing zone of the vacuum chamber based on the determined magnitude of the residual magnetic field.

### BRIEF DESCRIPTION OF THE DRAWINGS

Various ones of the appended drawings merely illustrate example embodiments of the present disclosure and cannot be considered as limiting its scope.

FIG. 1 illustrates a vacuum chamber, such as an etching chamber, for manufacturing substrates using CCP, according to some example embodiments.

FIG. 2 illustrates a vacuum chamber enclosed by a magnetic shield structure to improve control of etch rate and plasma uniformity, according to some example embodiments.

FIG. 3A illustrates a perspective view of a vacuum chamber with a residual magnetic field within a processing zone with CCP, according to some example embodiments.

FIG. 3B illustrates a top view of the vacuum chamber of FIG. 3A, according to some example embodiments.

FIG. 3C illustrates a side view of the vacuum chamber of FIG. 3A, according to some example embodiments.

FIG. 4 illustrates a magnetic shield structure that may be used to enclose a vacuum chamber to reduce external magnetic field effects, according to some example embodiments.

FIG. 5A illustrates a perspective view of a vacuum chamber with a single-coil used as a magnetic field source to counteract a residual magnetic field, according to some example embodiments.

FIG. 5B is a side view of the vacuum chamber of FIG. 5A illustrating mounting options for the magnetic field source, according to some example embodiments.

FIG. 6 illustrates a perspective view of a vacuum chamber with multiple coils configured as a Helmholtz pair generating a magnetic field to counteract a residual magnetic field, according to some example embodiments.

FIG. 7 illustrates a perspective view of a vacuum chamber with multiple coils configured as multiple Helmholtz pairs generating multiple magnetic fields to counteract a residual magnetic field, according to some example embodiments.

FIG. 8 illustrates a top view of a vacuum chamber using multiple pairs of coils generating different magnetic fields to counteract a residual magnetic field, according to some example embodiments.

FIG. 9 illustrates a perspective view of a vacuum chamber using a permanent magnet to counteract a magnetic field within the vacuum chamber generated by a magnetized vacuum chamber component, according to some example embodiments.

FIG. 10A illustrates a perspective view of a vacuum chamber using multiple coils as well as an arrangement of ferromagnetic bars to generate magnetic fields with different directions counteracting a residual magnetic field, according to some example embodiments.

FIG. 10B, FIG. 10C, FIG. 10D, FIG. 10E, and FIG. 10F illustrates top views of the vacuum chamber of FIG. 10A, illustrating different arrangements of the ferromagnetic bars resulting in different types of magnetic fields that can be generated to counteract a residual magnetic field, according to some example embodiments.

FIG. 11 illustrates a perspective view of a vacuum chamber enclosed by a magnetic shield structure, according to some example embodiments.

FIG. 12 illustrates a perspective view of a vacuum chamber using magnetic shield structures to enclose magnetized external and internal components, according to some example embodiments.

FIG. 13 illustrates a vacuum chamber with different types of magnetic sensors and a magnetic field controller to configure one or more supplemental magnetic fields that counteract a residual magnetic field, according to some example embodiments.

FIG. 14 illustrates an arrangement of vacuum chambers in a manufacturing facility that can use the disclosed techniques to reduce, zero out, or make uniform multiple residual magnetic fields within the vacuum chambers, according to some example embodiments.

FIG. 15 is a flowchart of a method for controlling etch rate and plasma uniformity using magnetic fields in semiconductor manufacturing equipment, according to some example embodiments.

FIG. 16 is a block diagram illustrating an example of a machine upon which one or more example method embodiments may be implemented, or by which one or more example embodiments may be controlled.

### DETAILED DESCRIPTION

Example methods, systems, and computer programs are directed to controlling etch rate and plasma uniformity using magnetic fields in CCP-based semiconductor manufacturing equipment. Examples merely typify possible variations. Unless explicitly stated otherwise, components and functions are optional and may be combined or subdivided, and operations may vary in sequence or be combined or subdivided. In the following description, for purposes of explanation, numerous specific details are set forth to provide a thorough understanding of example embodiments. It will be evident to one skilled in the art, however, that the present subject matter may be practiced without these specific details.

The center of substrate uniformity is challenging to control since it depends on etch process conditions. When conditions change, uniformity may change as well. Static solutions to control the center of wafer uniformity (such as adjusting the ground electrode dimension) may not perform efficiently over a wide range of process conditions. Solutions involving process parameters may lead to unwanted side effects when modified to address uniformity.

Techniques discussed herein use shielding and supplemental magnetic fields to control residual magnetic fields within the vacuum chamber that may influence etch rate and center of substrate plasma uniformity. In some aspects, a magnetic shield structure may be used to at least partially enclose the vacuum chamber and reduce magnetic field presence (from Earth's magnetic field and other ambient magnetic fields such as external magnetized components) within the processing zone of the chamber (e.g., where the CCP volume is located). However, since the magnetic shield structure may have openings to accommodate various facilities of the vacuum chamber (e.g., openings to accommodate RF components and communication links, gas delivery, heaters, high-voltage clamps, substrate delivery mechanisms, etc.), the magnetic shield structure may still allow a residual magnetic field to enter the vacuum chamber and the processing zone.

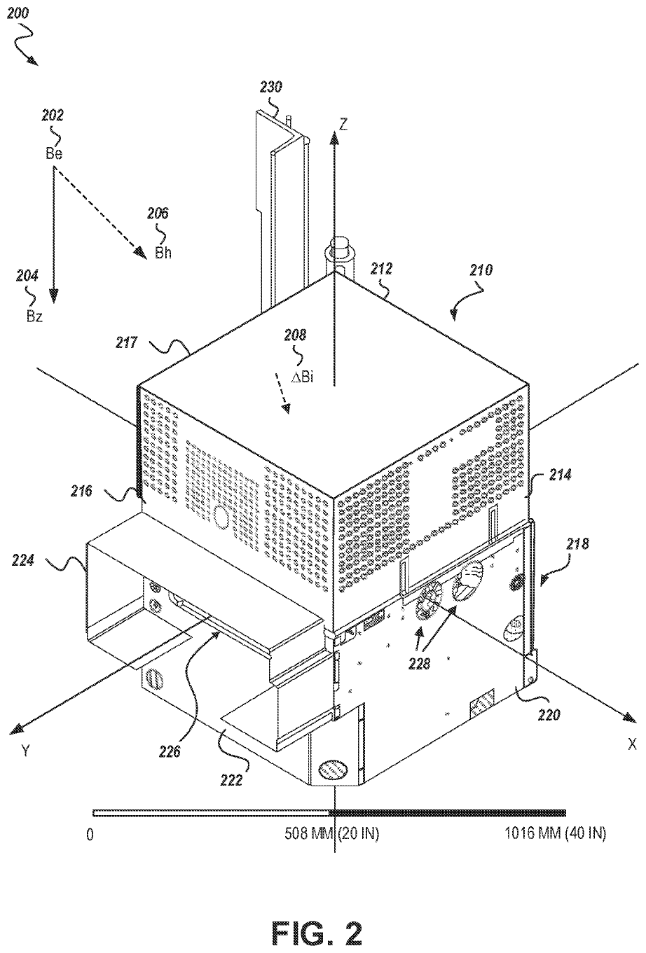

In some aspects and using the disclosed techniques, one or more supplemental (or trim) magnetic fields may be generated to counteract the residual magnetic field within the vacuum chamber. More specifically, one or more magnetic field sensors may be used to detect the residual magnetic field (ΔB) within the processing zone of the vacuum chamber. For example, the magnetic sensors may detect a vertical component (Bz) as well as a horizontal component (Bh) of the residual magnetic field. In some aspects, the magnetic sensors may detect one or more parameters of the residual magnetic field, such as a magnitude and a direction of the residual magnetic field (which may be determined by determining the magnitude and direction of each of the vertical component and horizontal component of the residual magnetic field). At least one magnetic field source may be used to generate one or more supplemental magnetic fields to counteract the residual magnetic field based on the detected magnitude and direction associated with the residual magnetic field. For example, the one or more supplemental magnetic fields can be generated within the processing zone of the vacuum chamber with the same magnitude but opposite direction so as to substantially reduce or cancel out the residual magnetic field. In other aspects, the one or more supplemental magnetic fields can be configured so that the residual magnetic field is configured to be uniform with the residual magnetic field in another vacuum chamber (e.g., residual magnetic fields in both vacuum chambers have the same desired direction and magnitude). Various techniques and options for configuring the magnetic shield structure as well as the at least one magnetic field source are illustrated in connection with FIG. 2-FIG. 14.

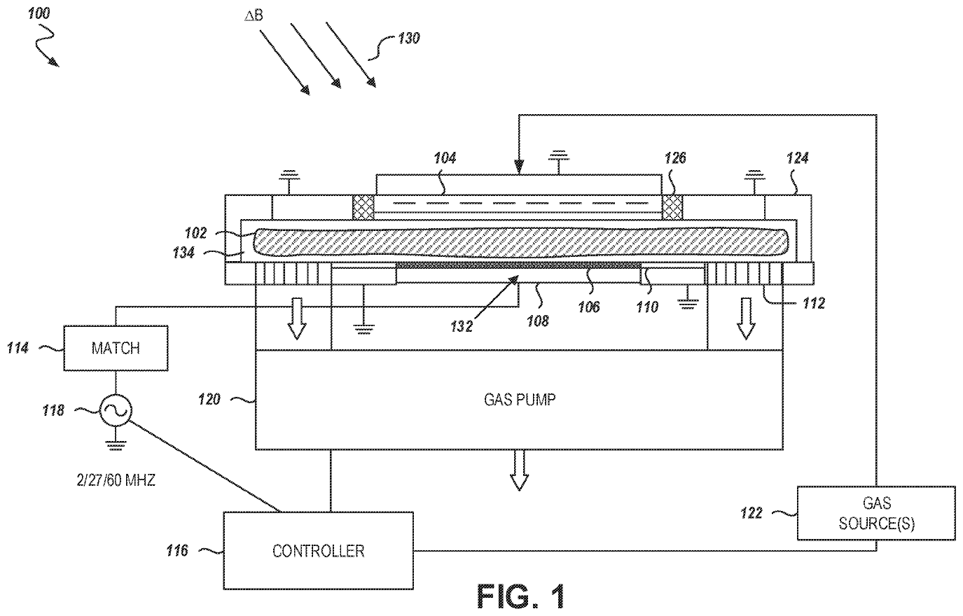

FIG. 1 illustrates a vacuum chamber 100 (e.g., an etching chamber) for manufacturing substrates using CCP, according to one embodiment. Exciting an electric field between two electrodes is one of the methods to obtain radio frequency (RF) gas discharge in a vacuum chamber. When an oscillating voltage is applied between the electrodes, the discharge obtained is referred to as a CCP discharge.

Plasma 102 may be created utilizing stable feedstock gases to obtain a wide variety of chemically reactive by-products created by the dissociation of the various molecules caused by electron-neutral collisions. The chemical aspect of etching involves the reaction of the neutral gas molecules and their dissociated by-products with the molecules of the to-be-etched surface and producing volatile molecules, which can be pumped away. When a plasma is created, the positive ions are accelerated from the plasma across a space-charge sheath separating the plasma from chamber walls to strike the wafer surface with enough energy to remove material from the wafer surface. This is known as ion bombardment or ion sputtering. Some industrial plasmas, however, do not produce ions with enough energy to efficiently etch a surface by purely physical means.

Controller 116 manages the operation of the vacuum chamber 100 by controlling the different elements in the chamber, such as RF generator 118, gas sources 122, and gas pump 120. In one embodiment, fluorocarbon gases, such as CF4 and C4F8, are used in a dielectric etch process for their anisotropic and selective etching capabilities, but the principles described herein can be applied to other plasma-creating gases. The fluorocarbon gases are readily dissociated into chemically reactive by-products that include smaller molecular and atomic radicals. These chemically reactive by-products etch away the dielectric material.

The vacuum chamber 100 illustrates a processing chamber with a top electrode 104 and a bottom electrode 108. The top electrode 104 may be grounded or coupled to an RF generator (not shown), and the bottom electrode 108 is coupled to the RF generator 118 via a matching network 114. The RF generator 118 provides RF power in one or multiple (e.g., two or three) different RF frequencies. According to the desired configuration of the vacuum chamber 100 for a particular operation, at least one of the three RF frequencies may be turned on or off. In the embodiment shown in FIG. 1, the RF generator 118 is configured to provide, e.g., 2 MHz, 27 MHz, and 60 MHz frequencies, but other frequencies are also possible.

The vacuum chamber 100 includes a gas showerhead on the top electrode 104 to input gas into the vacuum chamber 100 provided by the gas source(s) 122, and a perforated confinement ring 112 that allows the gas to be pumped out of the vacuum chamber 100 by gas pump 120. In some example embodiments, the gas pump 120 is a turbomolecular pump, but other types of gas pumps may be utilized.

When substrate 106 is present in the vacuum chamber 100, silicon focus ring 110 is situated next to the substrate 106 such that there is a uniform RF field at the bottom surface of the plasma 102 for uniform etching on the surface of the substrate 106. The embodiment of FIG. 1 shows a triode reactor configuration where the top electrode 104 is surrounded by a symmetric RF ground electrode 124. Insulator 126 is a dielectric that isolates the ground electrode 124 from the top electrode 104. Other implementations of the vacuum chamber 100 are also possible without changing the scope of the disclosed embodiments.

The substrate 106 can include, for example, wafers (e.g., having a diameter of 100 mm, 150 mm, 200 mm, 300 mm, 450 mm, or larger) and comprising, for example, elemental-semiconductor materials (e.g., silicon (Si) or germanium (Ge)) or compound-semiconductor materials (e.g., silicon germanium (SiGe) or gallium arsenide (GaAs)). Additionally, other substrates include, for example, dielectric materials such as quartz or sapphire (onto which semiconductor materials may be applied).

Each frequency generated by the RF generator 118 may be selected for a specific purpose in the substrate manufacturing process. In the example of FIG. 1, with RF powers provided at 2 MHz, 27 MHz, and 60 MHz, the 2 MHz RF power provides ion energy control, and the 27 MHz and 60 MHz powers provide control of the plasma density and the dissociation patterns of the chemistry. This configuration, where each RF power may be turned on or off, enables certain processes that use ultra-low ion energy on the substrates or wafers, and certain processes (e.g., soft etch for low-k materials) where the ion energy has to be low (e.g., under 700 or 200 eV).

In another embodiment, a 60 MHz RF power is used on the top electrode 104 to get ultra-low energies and very high density. This configuration allows chamber cleaning with high-density plasma when the substrate 106 is not in the vacuum chamber 100 while minimizing sputtering on the electrostatic chuck (ESC) surface. The ESC surface is exposed when the substrate 106 is not present, and any ion energy on the surface should be avoided, which is why the bottom 2 MHz and 27 MHz power supplies may be off during cleaning.

In some aspects, the vacuum chamber 100 is exposed to external magnetic fields, such as the Earth's magnetic field or other ambient magnetic fields (e.g., magnetic fields from magnetized components of the vacuum chamber such as a hoist as illustrated in FIG. 2). In this regard, the vacuum chamber 100 may be enclosed with a magnetic field structure (e.g., as illustrated in FIG. 2) to reduce the residual magnetic field ΔB 130 that may penetrate the processing zone 134 of the vacuum chamber 100. The presence of the residual magnetic field 130 in the vacuum chamber 100 is undesirable as it may negatively impact etch rate and plasma uniformity, especially around a center region 132 of the substrate 106 within the processing zone 134. Various techniques to further reduce or zero out the residual magnetic field 130 are discussed in connection with FIG. 2-FIG. 16.

FIG. 2 illustrates a vacuum chamber enclosed by a magnetic shield structure to improve control of etch rate and plasma uniformity, according to some example embodiments. Referring to FIG. 2, a vacuum chamber, such as vacuum chamber 100 of FIG. 1, may be enclosed by a magnetic shield structure 200 to reduce the effects of an external magnetic field (Be) 202, which includes a vertical component (Bz) 204 and a horizontal component (Bh) 206.

In an example embodiment, the magnetic shield structure 200 can include a top shielding portion 210 and a bottom shielding portion 218, where each shielding portion may include multiple shielding sub-portions as shown in FIG. 2. For example, the top shielding portion 210 can include shielding sub-portions 212, 214, 216, and 217. The bottom shielding portion 218 can include shielding sub-portions 220, 222, and 224. In some aspects, the magnetic shield structure 200 can include one or more openings 228 to accommodate various facilities used by the vacuum chamber, such as openings to accommodate RF components and communication links, ventilation, gas delivery, heaters, high-voltage clamps, substrate delivery mechanisms, etc.

In an example embodiment, the magnetic shield structure 200 can be manufactured from a high permeability material with a thickness of at least 40 mils. In an example embodiment, the various shielding sub-portions of the magnetic shield structure 200 can be bolted to (or securely attached via other means) to various surfaces of the vacuum chamber.

In an example embodiment, the shielding sub-portion 224 can be formed as a tunnel surrounding the vacuum chamber opening 226, which is used for delivery and removal of the substrate from the processing zone with the CCP.

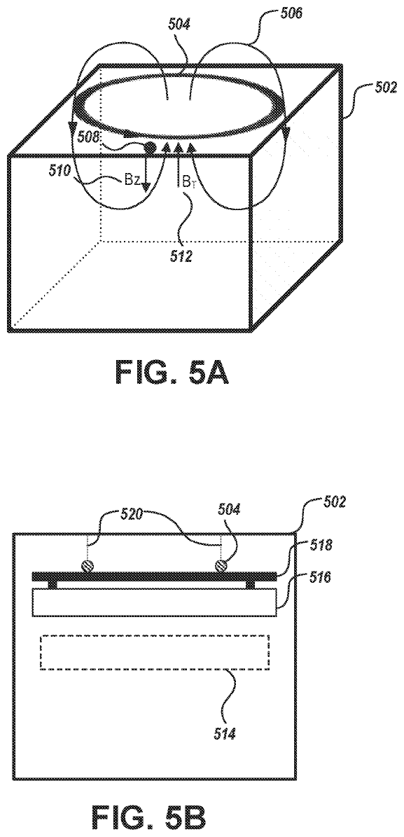

Due to imperfections of the magnetic shield structure 200 (e.g., the one or more openings 228 for accommodating vacuum chamber facilities), a residual magnetic field (ΔB) 208 can exist under the magnetic shield structure 200 and within the vacuum chamber 100 as a result of the external magnetic field (Be) 202 as well as external magnetic fields from magnetized chamber components (e.g., a magnetized hoist 230). Since such residual magnetic field 208 is internal to the vacuum chamber 100, FIG. 2 references the residual magnetic field 208 as ΔBi. In an example embodiment, one or more supplemental magnetic fields may be generated (e.g., using the techniques disclosed in connection with FIG. 5A-FIG. 10F) within the vacuum chamber 100 to counteract the effects of the residual magnetic field 208 (e.g., reduce or zero out a magnitude of the residual magnetic field 208 and/or change a direction of the residual magnetic field 208 so as to achieve uniformity among multiple shielded vacuum chambers at the same manufacturing location).

Additionally, any external magnetized chamber components (such as the hoist 230) can be demagnetized and/or shielded to further reduce the residual magnetic field 208. In some aspects, the hoist 230 can be magnetized in the order of 5-10 Gauss, which field can contribute to the residual magnetic field 208. Without the use of the magnetic shield structure 200, the residual magnetic field 208 may be in the magnitude of 0.5 Gauss in the vertical component (Bz) and 0.4 Gauss in the horizontal component (Bh). In some aspects, using the magnetic shield structure 200 can result in about 60% reduction of the residual magnetic field 208 (i.e., between 0.1 and 0.2 Gauss). In some aspects, by using one or more supplemental magnetic fields generated using the disclosed techniques, the residual magnetic field 208 within the vacuum chamber 100 may be reduced to below 0.1 Gauss.

In an example embodiment, the magnetic shield structure 200 can be configured as a cubicle structure surrounding the vacuum chamber 100, with each side of the cubicle structure measuring about 584 mm (approximately 23 inches) to 711 mm (approximately 28 inches) in length. In an example embodiment, the vacuum chamber opening 226 may measure about 50 mm (approximately 2 inches) in height.

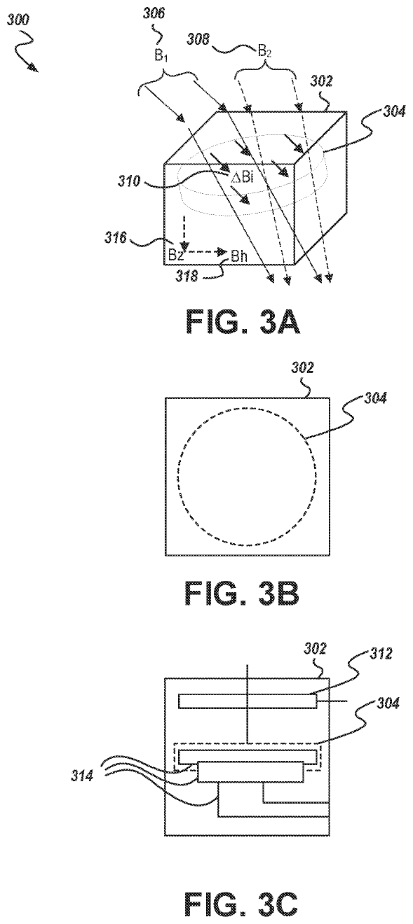

FIG. 3A illustrates a perspective view 300 of a vacuum chamber 302 with a residual magnetic field within a processing zone with CCP, according to some example embodiments. Referring to FIG. 3A, the vacuum chamber 302 can be exposed to a first external magnetic field 306 and a second external magnetic field 308. The vacuum chamber 302 may include a magnetic shield structure (e.g., a magnetic field structure such as magnetic shield structure 200 in FIG. 2), which is not visible in FIG. 3A.

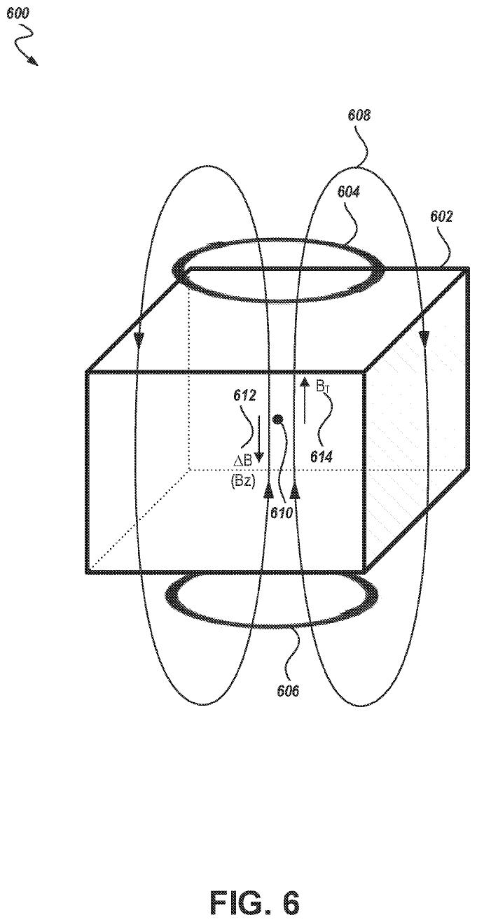

The vacuum chamber 302 includes a processing zone 304, which may be a volume filled with the CCP inside the vacuum chamber 302. The external magnetic fields 306 and 308 may penetrate the vacuum chamber 302, resulting in a residual magnetic field (ΔBi) 310. The residual magnetic field 310 may comprise a vertical component (Bz) 316 and a horizontal component (Bh) 318. In some aspects (e.g., as illustrated in FIG. 6), the horizontal component 318 may be zero and a supplemental magnetic field with only a vertical component can be generated within the vacuum chamber 302 to counteract the vertical component 316. In other aspects (e.g., as illustrated in FIG. 8), the vertical component 316 may be zero and a supplemental magnetic field with only a horizontal component can be generated within the vacuum chamber 302 to counteract the horizontal component 318.

FIG. 3B illustrates a top view of the vacuum chamber 302 of FIG. 3A, according to some example embodiments. FIG. 3C illustrates a side view of the vacuum chamber 302 of FIG. 3A, according to some example embodiments. Referring to FIG. 3C, the vacuum chamber 302 can include a top plate 312 as well as various facilities 314 used in connection with processing a substrate within the processing zone 304 (e.g., RF components and communication links, gas delivery, heaters, high-voltage clamps, substrate delivery mechanisms, etc.). The top plate 312 can include thermo-couplers and auxiliary components to handle the gas flow, power for temperature control, mechanical components associated with gas vacuum functionalities, etc.

In an example embodiment, the top plate 312 or the facilities 314 may be used for mounting at least one magnetic field source that can generate one or more supplemental magnetic fields to counter the residual magnetic field within the vacuum chamber 302.

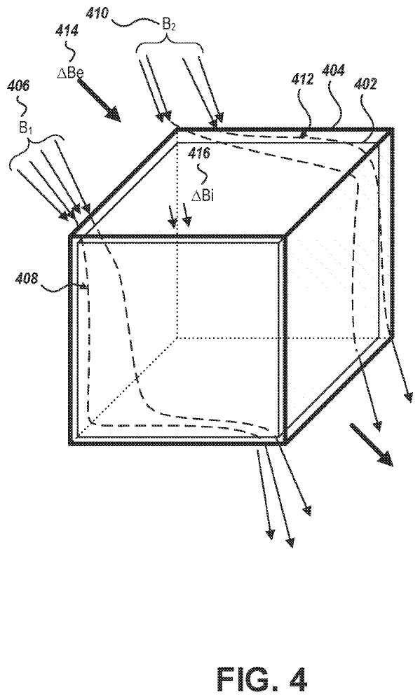

FIG. 4 illustrates a magnetic shield structure 404 that may be used to enclose a vacuum chamber 402 to reduce external magnetic field effects, according to some example embodiments. Referring to FIG. 4, the magnetic shield structure 404 may be similar to the magnetic shield structure 200 of FIG. 2, where shielding portions of the magnetic shield structure 404 may be attached to surfaces of the vacuum chamber 402. In some aspects, the magnetic shield structure 404 can be a single-wall or a double-wall magnetic shield structure, manufactured from a high permeability material (e.g., Mu-Metal).

The vacuum chamber 402 may be exposed to external magnetic fields 406 and 410, resulting in a combined external magnetic field 414. Due to imperfections of the magnetic shield structure 404, portions of the magnetic fields 406 and 410 can penetrate the magnetic shield structure 404 and the vacuum chamber 402 as magnetic fields 408 and 412 respectively. Consequently, a residual magnetic field 416 may be present within the vacuum chamber 402. In an example embodiment, one or more supplemental (or trim) magnetic fields can be generated by at least one magnetic field source using the techniques discussed herein (e.g., as illustrated in FIG. 5A-FIG. 10F) to counteract the residual magnetic field 416 that is present within the vacuum chamber 402.

FIG. 5A illustrates a perspective view of a vacuum chamber 502 with a single-coil used as a magnetic field source to counteract a residual magnetic field, according to some example embodiments. Referring to FIG. 5A, the vacuum chamber 502 may experience a residual magnetic field 510 (which includes primarily a vertical component Bz) measured at location 508 (which may be within the processing zone of the vacuum chamber). A single-coil 504 may be configured to generate a supplemental (or trim) magnetic field 506 within the vacuum chamber 502. The supplemental (or trim) magnetic field is also indicated as Bt 512, having an opposite direction to the direction of the residual magnetic field 510 and a similar magnitude.

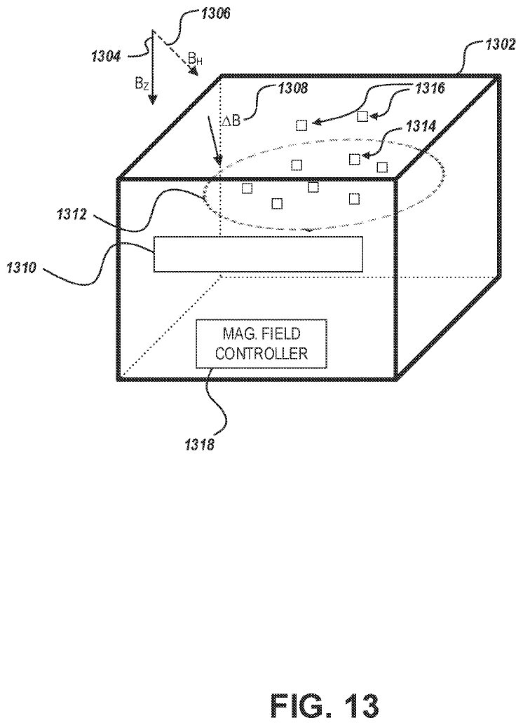

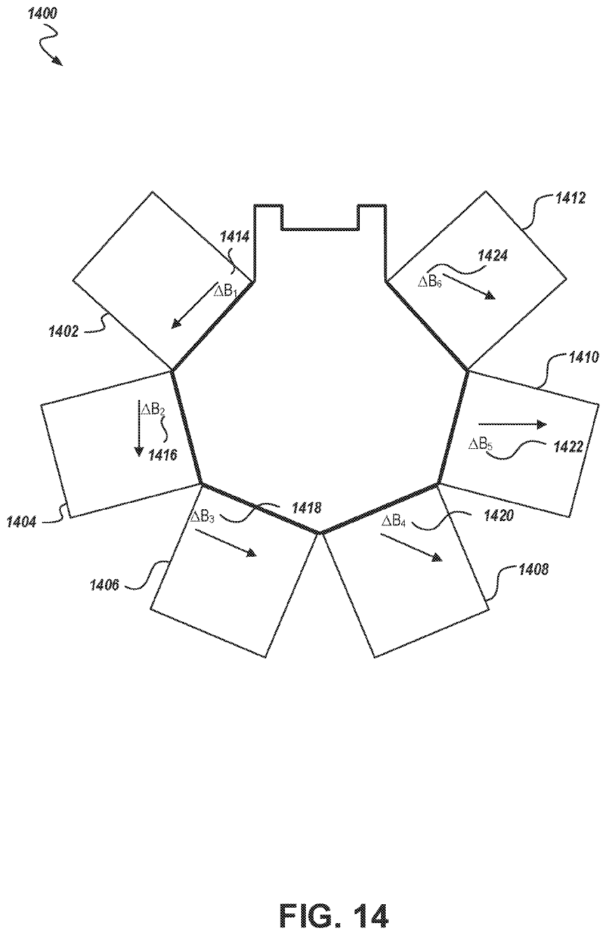

In an example embodiment, the residual magnetic field 510 may be detected and measured by a magnetic field sensor placed at or near location 508. Example magnetic field sensors that can be used to detect residual magnetic fields are illustrated in connection with FIG. 13. Additionally, a magnetic field controller (e.g., as illustrated in FIG. 13) may be used to adjust one or more characteristics of the supplemental magnetic field 512. For example, the magnetic field controller may adjust a current (e.g., a direct current (DC)) of the single-coil 504, thereby changing the magnitude of the supplemental magnetic field 512. In some aspects, the current may be adjusted so that the magnitude of the supplemental magnetic field 512 zeros out the magnitude of the residual magnetic field 510. In other aspects, the magnetic field controller may adjust the current through the single-coil 504 so that the resulting residual magnetic field 510 (after the supplemental magnetic field 512 is applied) achieves a target magnitude and/or direction (e.g., Bfab, a predetermined residual magnetic field magnitude matching the residual magnetic field magnitude in other vacuum chambers associated with a fabrication process (e.g., Bz˜Bfab)).

FIG. 5B is a side view of the vacuum chamber 502 of FIG. 5A illustrating mounting options for the magnetic field source 504, according to some example embodiments. Referring to FIG. 5B, in an example embodiment, the magnetic field source (e.g., the single-coil 504) may be mounted internally, within the vacuum chamber 502, and in proximity to the processing zone 514. In an example embodiment, the single-coil 504 may be mounted on a pedestal 518 secured to the top plate 516 of the vacuum chamber 502. In an example embodiment, the single-coil 504 may also be mounted to an inside surface of the vacuum chamber 502 (e.g., a top surface as illustrated in FIG. 5B) via connections 520.

In an example embodiment, the vacuum chamber 502 may be enclosed within a magnetic shield structure such as a magnetic shield structure 200 or 404. In an example embodiment, the single-coil 504 may be secured within the magnetic shield structure but outside of the vacuum chamber 502 (e.g., on an internal surface of the magnetic shield structure). In an example embodiment, the single-coil 504 may be placed outside of the magnetic shield structure and the vacuum chamber 502. In an example embodiment, multiple coils may be used as magnetic field sources to generate one or more supplemental magnetic fields (e.g., as illustrated in FIG. 6-FIG. 8), where each coil may be positioned differently, using the options discussed hereinabove in connection with FIG. 5A and FIG. 5B.

FIG. 6 illustrates a perspective view 600 of a vacuum chamber 602 with multiple coils configured as a Helmholtz pair generating a magnetic field to counteract a residual magnetic field, according to some example embodiments. Referring to FIG. 6, the vacuum chamber 602 may experience a residual magnetic field 612 (which includes primarily a vertical component Bz) measured at location 610 (which may be within the processing zone of the vacuum chamber 602). Multiple coils (e.g., two coils) 604-606 may be configured to generate a supplemental (or trim) magnetic field 608 within the vacuum chamber 602. The supplemental (or trim) magnetic field 608 is also indicated as Bt 614, having an opposite direction to the direction of the residual magnetic field 612 and a similar magnitude.

In an example embodiment, coils 604 and 606 may be configured as a Helmholtz pair. In an example embodiment, the residual magnetic field 612 may be detected and measured by a magnetic field sensor placed at or near location 610. Additionally, a magnetic field controller (e.g., as illustrated in FIG. 13) may be used to adjust one or more characteristics of the supplemental magnetic field 614. For example, the magnetic field controller may adjust a current of the Helmholtz pair of coils 604-606, thereby changing the magnitude of the supplemental magnetic field 614. In some aspects, the current may be adjusted so that the magnitude of the supplemental magnetic field 614 zeros out the magnitude of the residual magnetic field 612. In other aspects, the magnetic field controller may adjust the current through the Helmholtz pair so that the resulting residual magnetic field 612 (after the supplemental magnetic field 614 is applied) achieves a target magnitude and/or direction. In FIG. 6, in some aspects, the magnetic coils 604 and 606 could be more localized than the flat spirals shown in the figure to function as a classic Helmholtz pair.

In an example embodiment, the vacuum chamber 602 may be enclosed within a magnetic shield structure such as a magnetic shield structure 200 or 404. In an example embodiment, the Helmholtz pair of coils 604 and 606 may be secured within the magnetic shield structure but outside of the vacuum chamber 602 (e.g., on an internal surface of the magnetic shield structure). In an example embodiment, the Helmholtz pair of coils 604 and 606 may be placed outside of the magnetic shield structure and the vacuum chamber 602.

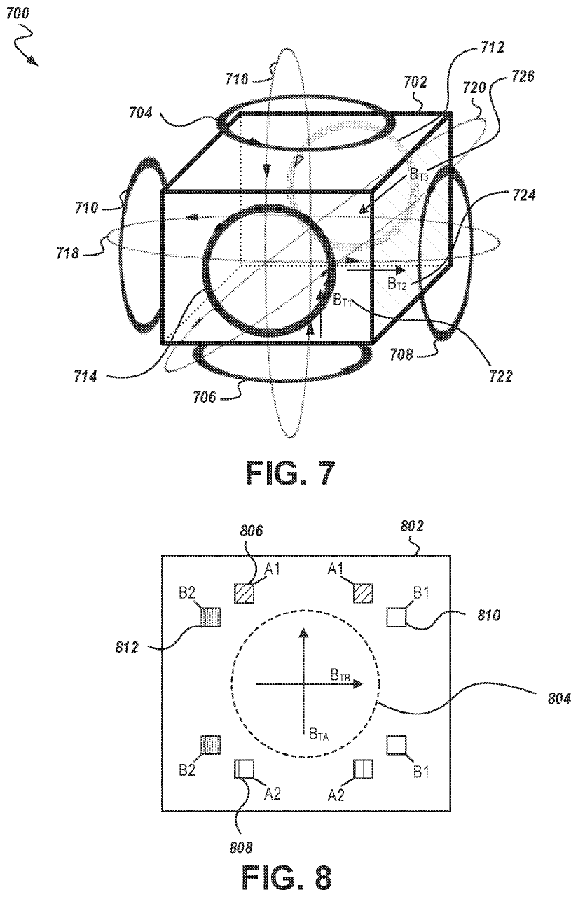

FIG. 7 illustrates a perspective view 700 of a vacuum chamber 702 with multiple coils configured as multiple Helmholtz pairs generating multiple magnetic fields to counteract a residual magnetic field, according to some example embodiments. Referring to FIG. 7, the vacuum chamber 702 may experience a residual magnetic field (not illustrated in FIG. 7). Multiple coils 704-714 may be configured to generate supplemental (or trim) magnetic fields 722-726 within the vacuum chamber 702.

In an example embodiment, coils 704-714 may be configured as Helmholtz pairs (e.g., coils 704 and 706 are configured as a first Helmholtz pair along a Z-axis, coils 708 and 710 are configured as a second Helmholtz pair along an X-axis, and coils 712 and 714 are configured as third Helmholtz pair along a Y-axis). In an example embodiment, the residual magnetic field may be detected and measured by a magnetic field sensor placed at or near the processing zone of the vacuum chamber 702. Additionally, a magnetic field controller (e.g., as illustrated in FIG. 13) may be used to adjust one or more characteristics of the supplemental magnetic fields 722, 724, and 726 (having corresponding magnetic field lines 716, 718, and 720). For example, the magnetic field controller may adjust a current of the Helmholtz pairs of coils 704-714, thereby changing the magnitude of each of the supplemental magnetic fields 722, 724, and 726. In some aspects, the current may be adjusted so that the magnitude of the supplemental magnetic fields 722-726 zeros out the magnitude of the residual magnetic field. In other aspects, the magnetic field controller may adjust the current through the Helmholtz pairs so that the resulting residual magnetic field (after one or more of the supplemental magnetic fields are applied) achieves a target magnitude and/or direction.

In an example embodiment, the magnetic field controller can use one or more magnetic field sensors to detect the residual magnetic field within the vacuum chamber 702. The magnetic field controller may then determine how many of the configured Helmholtz pairs can be activated based on the desired direction and/or magnitude of a supplemental magnetic field. For example, if the residual magnetic field is associated with a direction that coincides with the direction of only one of the supplemental magnetic fields 722-726, then only the corresponding Helmholtz pair associated with the matching direction is activated. Additionally, if the direction of the residual magnetic field is a combination of two or more of the directions of the supplemental magnetic fields 722-726, then the corresponding Helmholtz pairs associated with such directions are activated. In an example embodiment, the magnetic field controller may activate one or multiple of the available Helmholtz pairs based on the desired magnitude and/or direction of a resulting magnetic field (e.g., to achieve uniformity of residual magnetic fields between multiple vacuum chambers in a fabrication facility).

In an example embodiment, the vacuum chamber 702 may be enclosed within a magnetic shield structure such as a magnetic shield structure 200 or 404. In an example embodiment, the Helmholtz pairs of coils 704-714 may be secured within the magnetic shield structure but outside of the vacuum chamber 702 (e.g., on an internal surface of the magnetic shield structure). In an example embodiment, the Helmholtz pairs of coils 704-714 may be placed outside of the magnetic shield structure and the vacuum chamber 702.

In FIG. 7, in some aspects, the magnetic coils 704-714 could be more localized than the flat spirals shown in the figure to function as classic Helmholtz pairs.

FIG. 8 illustrates a top view of a vacuum chamber 802 using multiple pairs of coils generating different magnetic fields to counteract a residual magnetic field, according to some example embodiments. Referring to FIG. 8, vacuum chamber 802 includes a processing zone 804 for processing a substrate using CCP. FIG. 8 further illustrates coils 806, 808, 810, and 812, which may be similar to coils 712, 714, 708, and 710 of FIG. 7, respectively. In an example embodiment, coils 810 and 812 may be activated (e.g., as a Helmholtz pair) to generate a horizontal supplemental magnetic field Btb. In an example embodiment, coils 806 and 808 may be activated (e.g., as a Helmholtz pair) to generate another horizontal supplemental magnetic field Btz, which may be orthogonal to the horizontal supplemental magnetic field Btb (as illustrated in FIG. 8). In an example embodiment, such horizontal supplemental magnetic fields may be generated separately or together, with the same or different magnitudes, based on a desired magnitude and direction of a resulting residual magnetic field within the vacuum chamber 802.

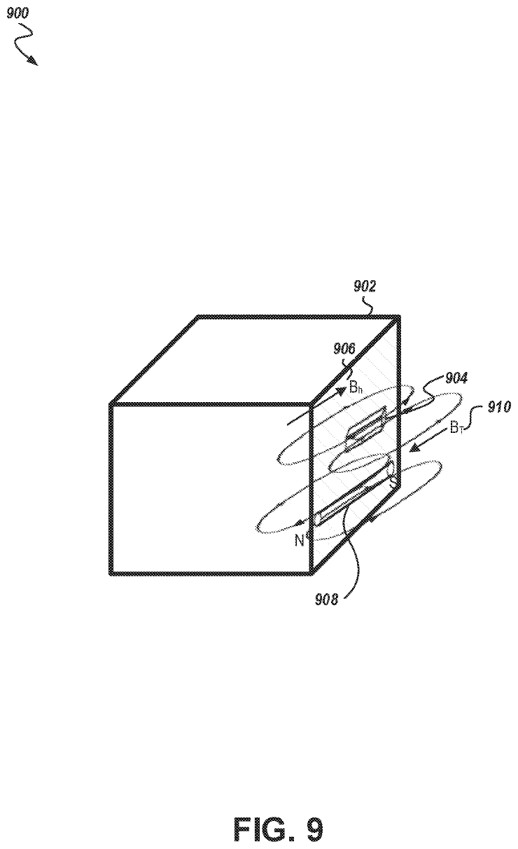

FIG. 9 illustrates a perspective view 900 of a vacuum chamber 902 using a permanent magnet to counteract a magnetic field within the vacuum chamber generated by a magnetized vacuum chamber component, according to some example embodiments. Referring to FIG. 9, vacuum chamber 902 may include a magnetized component 904, causing a residual magnetic field 906 within the vacuum chamber 902. In an example embodiment, a ferromagnetic bar (e.g., a permanent magnet) 908 may be placed within the vacuum chamber 902 so that a magnetic field 910 of the ferromagnetic bar 908 counteracts the residual magnetic field 906 caused by the magnetized component 904. In an example embodiment, the ferromagnetic bar 908 may be placed within a magnetic shield structure surrounding the vacuum chamber 902 but externally of the vacuum chamber 902. In an example embodiment, the ferromagnetic bar may be mounted outside of the magnetic shield structure surrounding vacuum chamber 902. In an example embodiment, multiple ferromagnetic bars may be used in place of the single ferromagnetic bar 908.

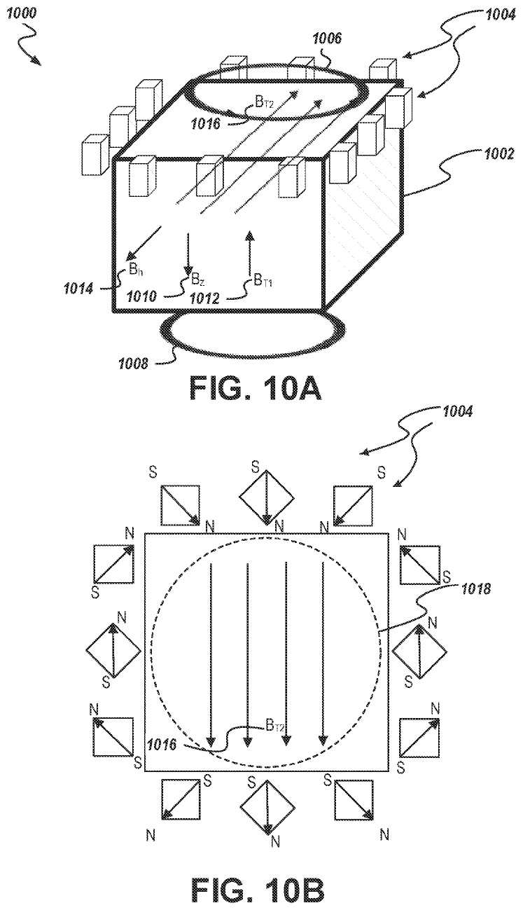

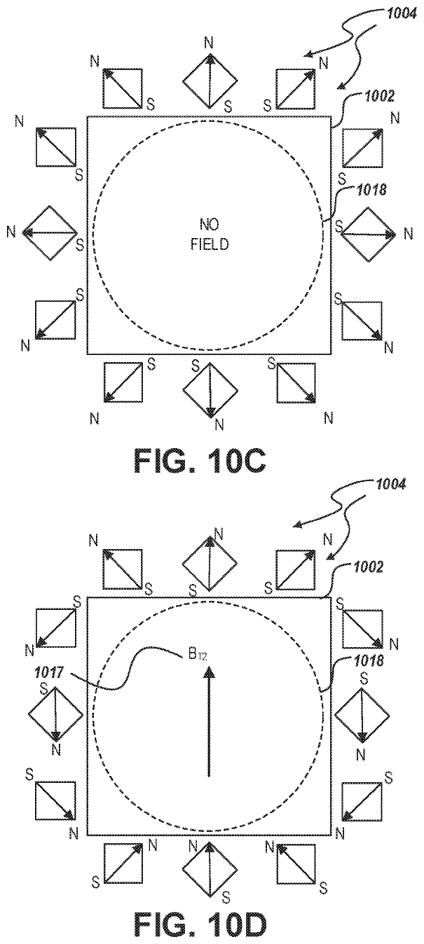

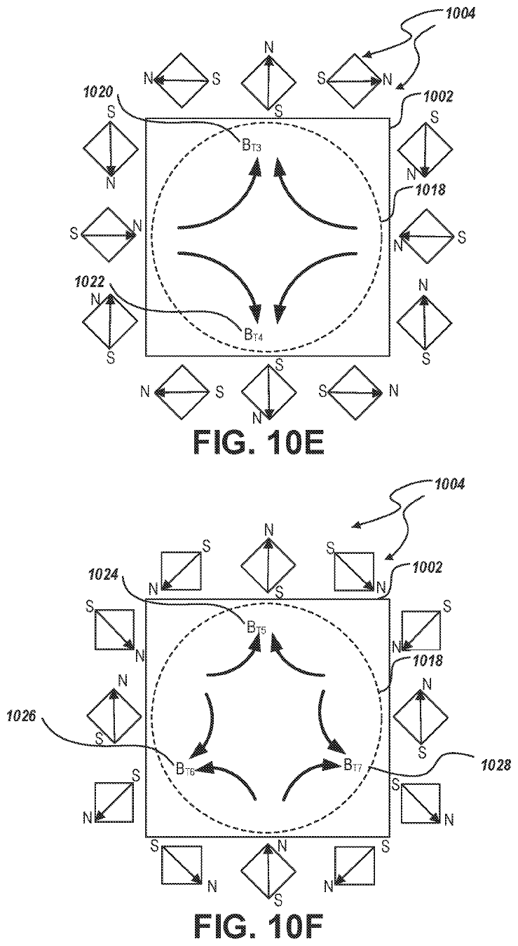

FIG. 10A illustrates a perspective view 1000 of a vacuum chamber 1002 with multiple coils as well as an arrangement of ferromagnetic bars to generate magnetic fields with different directions counteracting a residual magnetic field, according to some example embodiments. Referring to FIG. 10A, vacuum chamber 1002 may experience a residual magnetic field 1010 (which includes primarily a vertical component Bz) or a residual magnetic field 1014 (which includes primarily a horizontal component Bh). Multiple coils (e.g., two coils) 1006-1008 may be configured to generate a supplemental (or trim) magnetic field 1012 within the vacuum chamber 1002. The supplemental (or trim) magnetic field 1012 may have an opposite direction to the direction of the residual magnetic field 1010 and a similar magnitude.

In an example embodiment, multiple ferromagnetic bars 1004 can be placed around the vacuum chamber 1002 (on the inside or the outside of the chamber) and can be oriented to generate a supplemental magnetic field 1016 within the vacuum chamber 1002. The supplemental magnetic field 1016 may have an opposite direction to the direction of the residual magnetic field 1014 and a similar magnitude.

In an example embodiment, coils 1006 and 1008 may be configured as a Helmholtz pair. In an example embodiment, the residual magnetic fields 1010 and 1014 may be detected and measured by a magnetic field sensor placed at or near the processing zone (e.g., 1018) of the vacuum chamber 1002. Additionally, a magnetic field controller (e.g., as illustrated in FIG. 13) may be used to adjust one or more characteristics of the supplemental magnetic field 1012 or 1016. For example, the magnetic field controller may adjust a current of the Helmholtz pair of coils 1006-1008, thereby changing the magnitude of the supplemental magnetic field 1012. In some aspects, the current may be adjusted so that the magnitude of the supplemental magnetic field 1012 zeros out the magnitude of the residual magnetic field 1010. In other aspects, the magnetic field controller may adjust the current through the Helmholtz pair so that the resulting residual magnetic field 1010 (after the supplemental magnetic field 1012 is applied) achieves a target magnitude and/or direction.

In an example embodiment, the magnetic field controller may be used to automatically adjust individual directions of the ferromagnetic bars 1004 to achieve a desired horizontal magnetic field. Different configurations of the ferromagnetic bars resulting in different magnetic fields are illustrated in connection with FIG. 10B-FIG. 10F. For example, the entire set of ferromagnetic bars 1004 may be rotated to achieve the desired field or one or more individual ferromagnetic bars within the entire set may be rotated to achieve the desired field.

In an example embodiment, the magnetic field controller may be used to automatically adjust individual directions of the ferromagnetic bars 1004 to achieve a desired horizontal magnetic field. Different configurations of the ferromagnetic bars resulting in different magnetic fields are illustrated in connection with FIG. 10B-FIG. 10F. For example, the entire set of ferromagnetic bars 1004 may be rotated to achieve the desired field or one or more individual ferromagnetic bars within the entire set may be rotated to achieve the desired field.

FIG. 10B, FIG. 10C, FIG. 10D, FIG. 10E, and FIG. 10F illustrate top views of the vacuum chamber of FIG. 10A, illustrating different arrangements of the ferromagnetic bars resulting in different types of magnetic fields that can be generated to counteract a residual magnetic field, according to some example embodiments. Referring to FIG. 10B, the ferromagnetic bars 1004 are configured to generate a horizontal supplemental magnetic field 1016 within the processing zone 1018 of the vacuum chamber 1002. Referring to FIG. 10C, the ferromagnetic bars 1004 are configured so that no magnetic field is generated within the processing zone 1018. Referring to FIG. 10D, the ferromagnetic bars 1004 are configured so that a horizontal supplemental magnetic field 1017 is generated within the processing zone 1018. Referring to FIG. 10E, the ferromagnetic bars 1004 are configured so that horizontal supplemental magnetic fields 1020 and 1022 are generated within the processing zone 1018. Referring to FIG. 10F, the ferromagnetic bars 1004 are configured so that horizontal supplemental magnetic fields 1024, 1026, and 1028 are generated within the processing zone 1018.

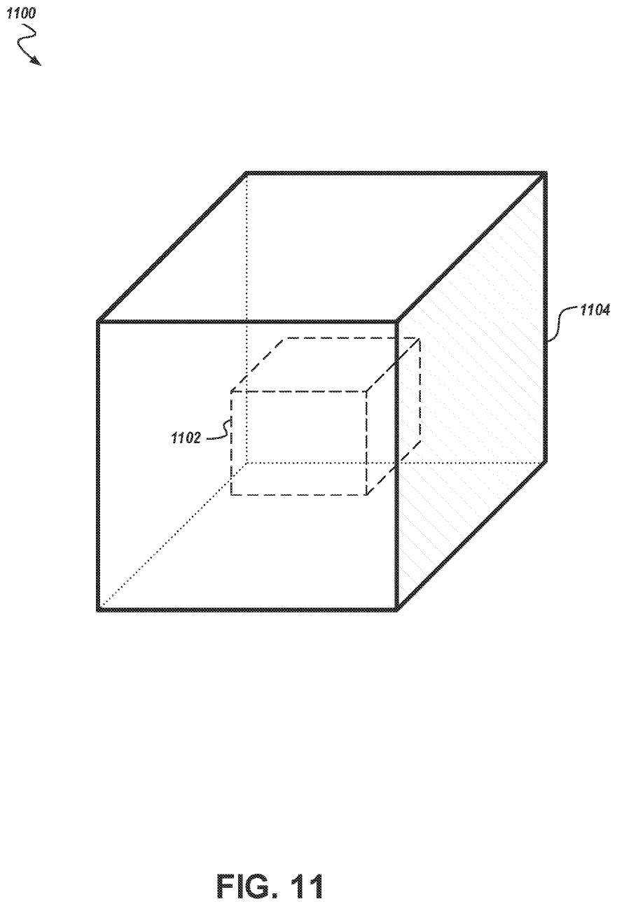

FIG. 11 illustrates a perspective view 1100 of a vacuum chamber 1102 enclosed by a magnetic shield structure 1104, according to some example embodiments. Referring to FIG. 11, the magnetic shield structure 1104 may differ from the magnetic shield structures 200 and 404 in that the magnetic shield structure 1104 may be a “big tent” style structure that encloses the vacuum chamber 1102 (rather than including shielding portions that are directly attached/bolted to the vacuum chamber). In this regard, one or more surfaces of the magnetic shield structure 1104 are not attached to corresponding surfaces of the vacuum chamber 1102.

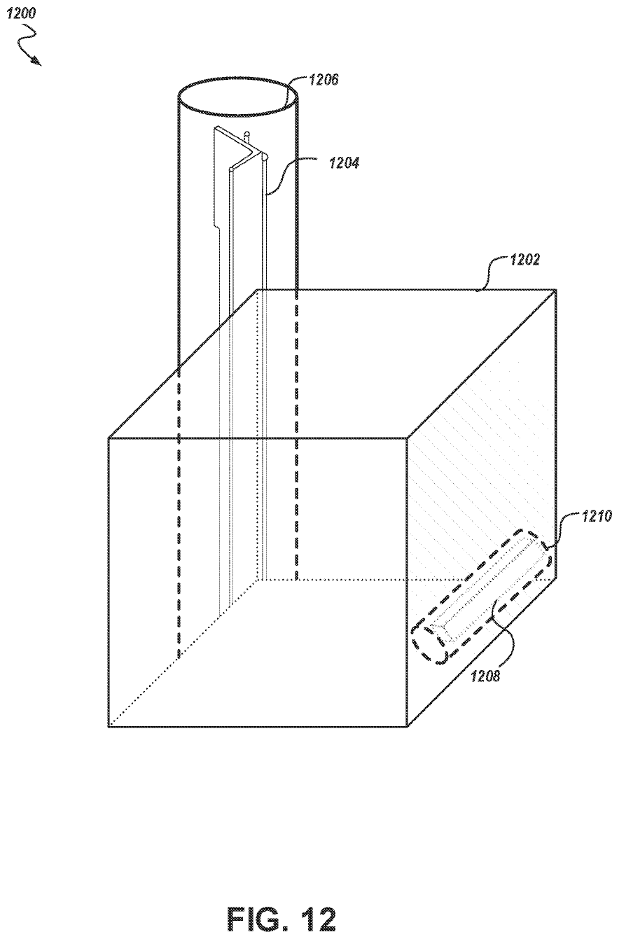

FIG. 12 illustrates a perspective view 1200 of a vacuum chamber 1202 using magnetic shield structures to enclose magnetized external and internal components, according to some example embodiments. Referring to FIG. 12, vacuum chamber 1202 can include magnetized external components, such as a magnetized hoist 1204, as well as magnetized internal components, such as a magnetized internal component 1208. In an example embodiment, to mitigate and reduce the residual magnetic fields within vacuum chamber 1202, partial magnetic shield structures may be used to shield the magnetized components. More specifically, as illustrated in FIG. 12, magnetic shield structure 1206 can be used to cover the magnetized hoist 1204, and a magnetic shield structure 1210 may be used to cover the magnetized internal component 1208.

In an example embodiment, any of the ferromagnetic bars (or permanent magnets) discussed herein may be used with a movable yoke. In this regard, by moving the yoke, rather than the entire ferromagnetic bar, the resulting supplemental magnetic field may be adjusted/changed.

FIG. 13 illustrates a vacuum chamber 1302 with different types of magnetic sensors and a magnetic field controller to configure one or more supplemental magnetic fields that counteract a residual magnetic field, according to some example embodiments. Referring to FIG. 13, vacuum chamber 1302 may be shielded (e.g., using magnetic shield structure 200 or 404) and exposed to external magnetic fields with a vertical component 1304 and a horizontal component 1306, resulting in a residual magnetic field 1308 within the vacuum chamber 1302.

In an example embodiment, the vacuum chamber 1302 includes a magnetic field controller 1318. The magnetic field controller 1318 comprises suitable circuitry, logic, interfaces, and/or code and is configured to receive magnetic field sensor data and adjust one or more characteristics of a supplemental magnetic field generated by at least one magnetic field source. In an example embodiment, a smart wafer 1312 may be loaded within the processing zone of the vacuum chamber 1302 from the opening 1310. The smart wafer 1312 may include a plurality of magnetic field sensors 1314 which are configured to detect and measure residual magnetic fields (e.g., residual magnetic field 1308) after the smart wafer 1312 is placed within the processing zone inside the vacuum chamber 1302. In an example embodiment, the magnetic field controller 1318 may also use one or more standalone magnetic field sensors 1316 to detect and measure residual magnetic fields such as residual magnetic field 1308.

In an example embodiment, the magnetic field controller 1318 may use the magnetic field sensors 1314 and/or 1316 to detect the magnitude and direction of the residual magnetic field 1308. The magnetic field controller 1318 may adjust at least one characteristic of a supplemental magnetic field generated to counter the residual magnetic field 1308. For example, the magnetic field controller may adjust the current through at least one magnetic field source that generates the supplemental magnetic field. Additionally, the magnetic field controller 1318 may activate or deactivate one or more magnetic field sources of a plurality of available magnetic field sources, to achieve zeroing out of a residual magnetic field or a residual magnetic field of desired magnitude and direction to achieve uniformity with other vacuum chambers in a fabrication facility.

In an example embodiment, magnetic field sensors 1314 and/or 1316 may be used for initial measurement so that the magnetic field controller 1318 may perform adjustments resulting in generating a supplemental magnetic field with desired magnitude and direction. Periodic measurements and adjustments may be performed using magnetic field sensors 1314 and/or 1316. In an example embodiment, standalone magnetic field sensors 1316 may be used for automatic (dynamic) measurements and adjustments in the characteristics of the supplemental magnetic fields. In an example embodiment, one magnetic field sensor (or a set of magnetic field sensors) may be used in connection with a single magnetic field source, so that different sensors may be associated with different magnetic field sources. In an example embodiment, the magnetic field controller 1318 may communicate wirelessly with magnetic field sensors 1314 and 1316 to receive sensor data.

FIG. 14 illustrates an arrangement 1400 of vacuum chambers in a manufacturing facility that can use the disclosed techniques to reduce, zero out, or make uniform multiple residual magnetic fields within the vacuum chambers, according to some example embodiments. Referring to FIG. 14, arrangement 1400 may be located within a semiconductor fabrication facility and may include multiple vacuum chambers such as vacuum chambers 1402, 1404, 1406, 1408, 1410, and 1412. Each of the vacuum chambers may be magnetically shielded and may be exposed to different external magnetic fields, resulting in different residual magnetic fields within each vacuum chamber. More specifically, vacuum chambers 1402, 1404, 1406, 1408, 1410, and 1412 are associated with corresponding residual magnetic fields 1414, 1416, 1418, 1420, 1422, and 1424. In an example embodiment, one or more of the techniques discussed herein may be used to zero out each of the residual magnetic fields within the vacuum chambers or achieve a uniform residual magnetic field of the same magnitude and direction within each of the vacuum chambers.

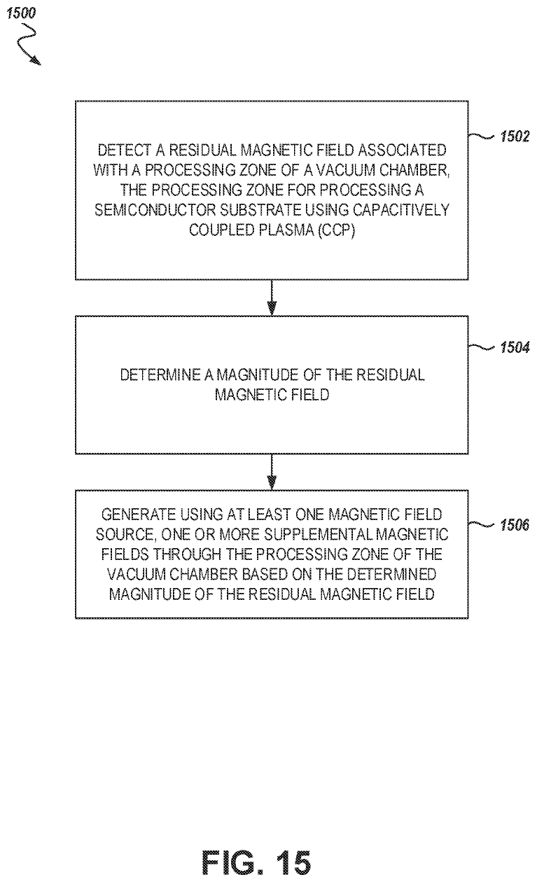

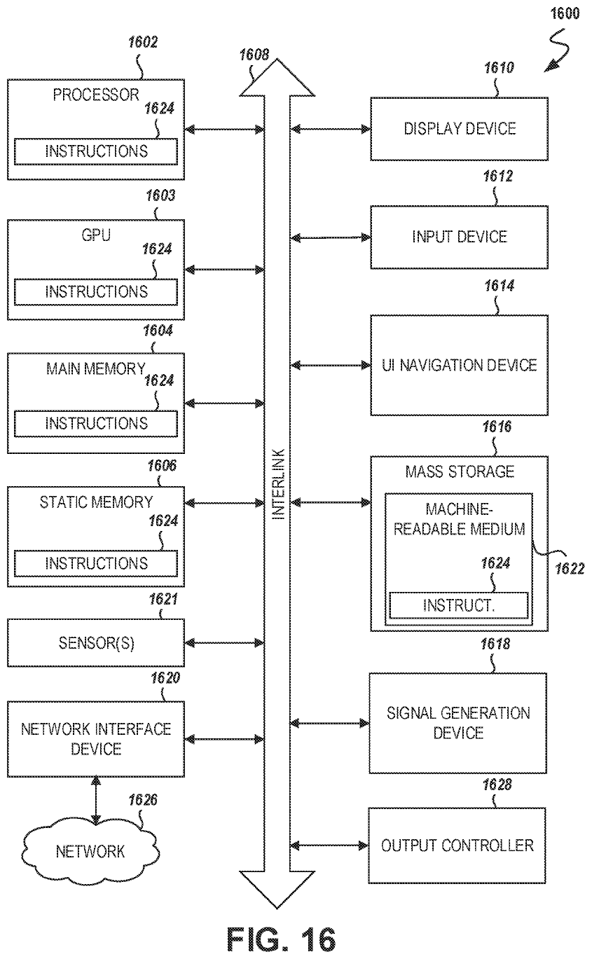

FIG. 15 is a flowchart of a method 1500 for controlling etch rate and plasma uniformity using magnetic fields in semiconductor manufacturing equipment, according to some example embodiments. The method 1500 includes operations 1502, 1504, and 1506, which may be performed by a magnetic field controller such as magnetic field controller 1318 of FIG. 13 or processor 1602 of FIG. 16. Referring to FIG. 15, at operation 1502, a residual magnetic field associated with a processing zone of a vacuum chamber may be detected. The residual magnetic field may be a field detected inside the vacuum chamber or outside the vacuum chamber (e.g., within a shielding structure surrounding the vacuum chamber or outside the shielding structure). The processing zone may be used for processing a semiconductor substrate using capacitively coupled plasma (CCP). For example, the magnetic field controller 1318 may use one or more magnetic field sensors 1314 and 1316 to detect a residual magnetic field within the processing zone of the vacuum chamber 1302. At operation 1504, a magnitude of the residual magnetic field is determined. For example, the magnetic field controller 1318 may use the magnetic field sensors to determine the magnitude (and direction) of the detected residual magnetic field. At operation 1506, one or more supplemental magnetic fields may be generated through the processing zone of the vacuum chamber using at least one magnetic field source. For example, the magnetic field controller 1318 may configure one or more magnetic field sources (e.g., one or more of the magnetic field sources illustrated in FIG. 5A-FIG. 10F) to generate one or more supplemental magnetic fields based on the determined magnitude of the residual magnetic field. In an example embodiment, the supplemental magnetic fields may be generated while the vacuum chamber is shielded using at least one magnetic shield structure discussed herein.

FIG. 16 is a block diagram illustrating an example of a machine 1600 upon or by which one or more example process embodiments described herein may be implemented or controlled. In alternative embodiments, the machine 1600 may operate as a standalone device or may be connected (e.g., networked) to other machines. In a networked deployment, machine 1600 may operate in the capacity of a server machine, a client machine, or both in server-client network environments. In an example, the machine 1600 may act as a peer machine in a peer-to-peer (P2P) (or other distributed) network environment. Further, while only a single machine 1600 is illustrated, the term “machine” shall also be taken to include any collection of machines that individually or jointly execute a set (or multiple sets) of instructions to perform any one or more of the methodologies discussed herein, such as via cloud computing, software as a service (SaaS), or other computer cluster configurations.

Examples, as described herein, may include, or may operate by, logic, several components, or mechanisms. Circuitry is a collection of circuits implemented in tangible entities that include hardware (e.g., simple circuits, gates, logic). Circuitry membership may be flexible over time and underlying hardware variability. Circuitries include members that may, alone or in combination, perform specified operations when operating. In an example, the hardware of the circuitry may be immutably designed to carry out a specific operation (e.g., hardwired). In an example, the hardware of the circuitry may include variably connected physical components (e.g., execution units, transistors, simple circuits) including a computer-readable medium physically modified (e.g., magnetically, electrically, by the moveable placement of invariant massed particles) to encode instructions of the specific operation. In connecting the physical components, the underlying electrical properties of a hardware constituent are changed (for example, from an insulator to a conductor or vice versa). The instructions enable embedded hardware (e.g., the execution units or a loading mechanism) to create members of the circuitry in hardware via the variable connections to carry out portions of the specific operation when in operation. Accordingly, the computer-readable medium is communicatively coupled to the other components of the circuitry when the device is operating. In some aspects, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine (e.g., computer system) 1600 may include a hardware processor 1602 (e.g., a central processing unit (CPU), a hardware processor core, or any combination thereof), a graphics processing unit (GPU) 1603, a main memory 1604, and a static memory 1606, some or all of which may communicate with each other via an interlink (e.g., bus) 1608. The machine 1600 may further include a display device 1610, an alphanumeric input device 1612 (e.g., a keyboard), and a user interface (UI) navigation device 1614 (e.g., a mouse). In an example embodiment, the display device 1610, alphanumeric input device 1612, and UI navigation device 1614 may be a touch screen display. The machine 1600 may additionally include a mass storage device (e.g., drive unit) 1616, a signal generation device 1618 (e.g., a speaker), a network interface device 1620, and one or more sensors 1621, such as a Global Positioning System (GPS) sensor, compass, accelerometer, or another sensor. The machine 1600 may include an output controller 1628, such as a serial (e.g., universal serial bus (USB)), parallel, or other wired or wireless (e.g., infrared (IR), near field communication (NFC)) connection to communicate with or control one or more peripheral devices (e.g., a printer, card reader).

In an example embodiment, the hardware processor 1602 may perform the functionalities of the magnetic field controller 1318 discussed hereinabove, in connection with at least FIG. 13.

The mass storage device 1616 may include a machine-readable medium 1622 on which is stored one or more sets of data structures or instructions 1624 (e.g., software) embodying or utilized by any one or more of the techniques or functions described herein. The instructions 1624 may also reside, completely or at least partially, within the main memory 1604, within the static memory 1606, within the hardware processor 1602, or within the GPU 1603 during execution thereof by the machine 1600. In an example embodiment, one or any combination of the hardware processor 1602, the GPU 1603, the main memory 1604, the static memory 1606, or the mass storage device 1616 may constitute machine-readable media.

While the machine-readable medium 1622 is illustrated as a single medium, the term “machine-readable medium” may include a single medium or multiple media, (e.g., a centralized or distributed database, and/or associated caches and servers) configured to store the one or more instructions 1624.

The term “machine-readable medium” may include any medium that is capable of storing, encoding, or carrying instructions 1624 for execution by the machine 1600 and that causes the machine 1600 to perform any one or more of the techniques of the present disclosure, or that is capable of storing, encoding, or carrying data structures used by or associated with such instructions 1624. Non-limiting machine-readable medium examples may include solid-state memories and optical and magnetic media. In an example, a massed machine-readable medium comprises a machine-readable medium 1622 with a plurality of particles having invariant (e.g., rest) mass. Accordingly, massed machine-readable media are not transitory propagating signals. Specific examples of massed machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The instructions 1624 may further be transmitted or received over a communications network 1626 using a transmission medium via the network interface device 1620.

Implementation of the preceding techniques may be accomplished through any number of specifications, configurations, or example deployments of hardware and software. It should be understood that the functional units or capabilities described in this specification may have been referred to or labeled as components or modules, to emphasize their implementation independence. Such components may be embodied by any number of software or hardware forms. For example, a component or module may be implemented as a hardware circuit comprising custom very-large-scale integration (VLSI) circuits or gate arrays, off-the-shelf semiconductors such as logic chips, transistors, or other discrete components. A component or module may also be implemented in programmable hardware devices such as field-programmable gate arrays, programmable array logic, programmable logic devices, or the like. Components or modules may also be implemented in software for execution by various types of processors. An identified component or module of executable code may, for instance, comprise one or more physical or logical blocks of computer instructions, which may, for instance, be organized as an object, procedure, or function. Nevertheless, the executables of an identified component or module need not be physically located together but may comprise disparate instructions stored in different locations which, when joined logically together, comprise the component or module and achieve the stated purpose for the component or module.

Indeed, a component or module of executable code may be a single instruction, or many instructions, and may even be distributed over several different code segments, among different programs, and across several memory devices or processing systems. In particular, some aspects of the described process (such as code rewriting and code analysis) may take place on a different processing system (e.g., in a computer in a data center), than that in which the code is deployed (e.g., in a computer embedded in a sensor or robot). Similarly, operational data may be identified and illustrated herein within components or modules and may be embodied in any suitable form and organized within any suitable type of data structure. The operational data may be collected as a single data set or may be distributed over different locations including over different storage devices, and may exist, at least partially, merely as electronic signals on a system or network. The components or modules may be passive or active, including agents operable to perform desired functions.

### ADDITIONAL NOTES & EXAMPLES

Example 1 is a semiconductor substrate processing apparatus, comprising: a vacuum chamber including a processing zone for processing a substrate using capacitively coupled plasma (CCP); a magnetic field sensor configured to detect a residual magnetic field within the vacuum chamber; at least one magnetic field source configured to generate one or more supplemental magnetic fields through the processing zone of the vacuum chamber; and a magnetic field controller coupled to the magnetic field sensor and the at least one magnetic field source, the magnetic field controller configured to adjust at least one characteristic of the one or more supplemental magnetic fields, causing the one or more supplemental magnetic fields to reduce the residual magnetic field to a pre-determined value.

In Example 2, the subject matter of Example 1 includes, wherein the magnetic field sensor is a wafer sensor placed within the processing zone of the vacuum chamber.

In Example 3, the subject matter of Example 2 includes, wherein the wafer sensor comprises an array of magnetic field sensors configured to measure magnitudes of the residual magnetic field at a plurality of locations within the processing zone; and wherein the magnetic field controller adjusts the at least one characteristic of the one or more supplemental magnetic fields based on the measured magnitudes.

In Example 4, the subject matter of Example 3 includes, wherein the at least one characteristic is one or both of a magnitude and a direction of the one or more supplemental magnetic fields.

In Example 5, the subject matter of Example 4 includes, wherein the magnetic field controller adjusts a current through the at least one magnetic field source to adjust the magnitude of the one or more supplemental magnetic fields.

In Example 6, the subject matter of Examples 1-5 includes, wherein the magnetic field sensor is configured to measures a magnitude of the residual magnetic field.

In Example 7, the subject matter of Example 6 includes, wherein the at least one characteristic comprises a magnitude and a direction of the one or more supplemental magnetic fields.

In Example 8, the subject matter of Example 7 includes, wherein the magnetic field controller is configured to set a current through the at least one magnetic field source resulting in the magnitude of the one or more supplemental magnetic fields being equal to the magnitude of the residual magnetic field, and a direction of the one or more supplemental magnetic fields being opposite to a direction of the residual magnetic field.

In Example 9, the subject matter of Examples 1-8 includes, a magnetic shield structure configured to enclose the vacuum chamber.

In Example 10, the subject matter of Example 9 includes, wherein the magnetic shield structure comprises a tunnel portion surrounding an opening in the vacuum chamber for receiving the substrate.

In Example 11, the subject matter of Examples 9-10 includes, wherein the magnetic shield structure comprises a shielding portion at least partially enclosing a magnetized component of the vacuum chamber that is external to the processing zone.

In Example 12, the subject matter of Example 11 includes, wherein the magnetized component is a hoist that is externally attached to the vacuum chamber.

In Example 13, the subject matter of Examples 9-12 includes, wherein the magnetic shield structure comprises a plurality of shield portions attached to a corresponding plurality of surfaces of the vacuum chamber.

In Example 14, the subject matter of Examples 9-13 includes, wherein the magnetic shield structure is configured to enclose the vacuum chamber, forming a plurality of air gaps between corresponding parallel surfaces of the vacuum chamber and the magnetic shield structure.

In Example 15, the subject matter of Examples 9-14 includes, wherein the at least one magnetic field source is a single-coil comprising a plurality of windings.

In Example 16, the subject matter of Example 15 includes, wherein the single-coil is mounted within the magnetic shield structure and externally to the vacuum chamber.

In Example 17, the subject matter of Examples 15-16 includes, wherein the single-coil is mounted within the magnetic shield structure and internally to the vacuum chamber.

In Example 18, the subject matter of Example 17 includes, wherein the single-coil is mounted within one of the following: a top plate of the vacuum chamber; a showerhead of the vacuum chamber; and a gas distribution plate of the vacuum chamber.

In Example 19, the subject matter of Examples 15-18 includes, wherein the single-coil is mounted externally to the magnetic shield structure so that at least one of the plurality of windings surrounds the magnetic shield structure.

In Example 20, the subject matter of Examples 15-19 includes, wherein the single-coil is mounted on a support structure attached to a surface of the magnetic shield structure.

In Example 21, the subject matter of Examples 15-20 includes, wherein the single-coil is mounted on a support structure attached to a surface of the vacuum chamber.

In Example 22, the subject matter of Examples 9-21 includes, wherein the at least one magnetic field source comprises a plurality of coils, each coil comprising a plurality of windings.

In Example 23, the subject matter of Example 22 includes, wherein the plurality of coils are mounted within the magnetic shield structure and externally to the vacuum chamber.

In Example 24, the subject matter of Examples 22-23 includes, wherein the plurality of coils are mounted within the magnetic shield structure and internally to the vacuum chamber.

In Example 25, the subject matter of Example 24 includes, wherein the plurality of coils are mounted within one of the following: a top plate of the vacuum chamber; a showerhead of the vacuum chamber; and a gas distribution plate of the vacuum chamber.

In Example 26, the subject matter of Examples 22-25 includes, wherein the plurality of coils are mounted externally to the magnetic shield structure so that at least one of the plurality of windings surrounds the magnetic shield structure.

In Example 27, the subject matter of Examples 22-26 includes, wherein the plurality of coils are mounted on a support structure attached to a surface of the magnetic shield structure.

In Example 28, the subject matter of Examples 22-27 includes, wherein the plurality of coils are mounted on a support structure attached to a surface of the vacuum chamber.

In Example 29, the subject matter of Examples 22-28 includes, wherein the plurality of coils comprises: a first coil mounted internally to the vacuum chamber, the first coil configured to generate a first supplemental magnetic field of the one or more supplemental magnetic fields with a direction that is opposite a vertical component (Bz) of the residual magnetic field.

In Example 30, the subject matter of Example 29 includes, wherein the plurality of coils comprises: at least a second coil mounted within the magnetic shield structure and externally to the vacuum chamber, the at least second coil configured to generate at least a second supplemental magnetic field of the one or more supplemental magnetic fields with a direction that is opposite a horizontal component (Bh) of the residual magnetic field.

In Example 31, the subject matter of Examples 22-30 includes, wherein the plurality of coils includes a Helmholtz pair configured to generate at least one of the supplemental magnetic fields along a vertical axis or a horizontal axis of the vacuum chamber.

In Example 32, the subject matter of Example 31 includes, wherein the plurality of coils includes at least three Helmholtz pairs, the three Helmholtz pairs disposed on mutually orthogonal axes of the vacuum chamber.

In Example 33, the subject matter of Examples 9-32 includes, wherein the at least one magnetic field source comprises an arrangement of ferromagnetic bars.

In Example 34, the subject matter of Example 33 includes, wherein the ferromagnetic bars are mounted within the magnetic shield structure and externally to the vacuum chamber.

In Example 35, the subject matter of Examples 33-34 includes, wherein the ferromagnetic bars are mounted within the magnetic shield structure and internally to the vacuum chamber.

In Example 36, the subject matter of Examples 33-35 includes, wherein the ferromagnetic bars include one or more of a group of materials comprising: a nickel-zinc (NiZn) ferrite, magnesium zinc (MgZn) ferrite, a ferrite made of Nickel Magnesium (NiMg) alloy, manganese zinc (MnZn) ferrite, a powdered-iron, and a combination thereof

In Example 37, the subject matter of Examples 1-36 includes, wherein the magnetic field controller is configured to adjust one or both of a magnitude and a direction of the one or more supplemental magnetic fields.

In Example 38, the subject matter of Example 37 includes, wherein the magnetic field controller is configured to change a current within the at least one magnetic field source to adjust the direction; and configure the at least one magnetic field source to include multiple magnetic field sources disposed at least orthogonally to each other.

Example 39 is a method for processing a semiconductor substrate using a vacuum chamber, the method comprising: detecting a residual magnetic field within a processing zone of the vacuum chamber, the processing zone for processing the semiconductor substrate using capacitively coupled plasma (CCP); determining a magnitude of the residual magnetic field; and generating using at least one magnetic field source, one or more supplemental magnetic fields through the processing zone of the vacuum chamber based on the determined magnitude of the residual magnetic field.

In Example 40, the subject matter of Example 39 includes, wherein determining the magnitude further comprises: determining a magnitude of a vertical component (Bz) of the residual magnetic field and determining a magnitude of a horizontal component (Bh) of the residual magnetic field.

In Example 41, the subject matter of Example 40 includes, activating a first magnetic field source of at least one magnetic field source to generate a first supplemental magnetic field that reduces the magnitude of the vertical component of the residual magnetic field; and activating a second magnetic field source of the at least one magnetic field source to generate a second supplemental magnetic field that reduces the magnitude of the horizontal component of the residual magnetic field.

In Example 42, the subject matter of Examples 39-41 includes, providing a magnetic shield structure enclosing the vacuum chamber.

In Example 43, the subject matter of Example 42 includes, wherein the magnetic shield structure comprises a tunnel portion surrounding an opening in the vacuum chamber for receiving the substrate.

In Example 44, the subject matter of Examples 42-43 includes, wherein the magnetic shield structure comprises a shielding portion at least partially enclosing a magnetized component of the vacuum chamber that is external to the processing zone.

In Example 45, the subject matter of Example 44 includes, wherein the magnetized component is a hoist that is externally attached to the vacuum chamber.

In Example 46, the subject matter of Examples 42-45 includes, wherein the magnetic shield structure comprises a plurality of shield portions attached to a corresponding plurality of surfaces of the vacuum chamber.

In Example 47, the subject matter of Examples 42-46 includes, wherein the magnetic shield structure is configured to enclose the vacuum chamber, forming a plurality of air gaps between corresponding parallel surfaces of the vacuum chamber and the magnetic shield structure.

Example 48 is a non-transitory machine-readable storage medium including instructions that, when executed by a machine, cause the machine to perform operations comprising: detecting a residual magnetic field within a processing zone of a vacuum chamber, the processing zone for processing a semiconductor substrate using capacitively coupled plasma (CCP); determining a magnitude of the residual magnetic field, and generating one or more supplemental magnetic fields through the processing zone of the vacuum chamber based on the determined magnitude of the residual magnetic field.

In Example 49, the subject matter of Example 48 includes, the operations further comprising: determining a magnitude of a vertical component (Bz) of the residual magnetic field; and determining a magnitude of a horizontal component (Bh) of the residual magnetic field.

In Example 50, the subject matter of Example 49 includes, the operations further comprising: activating a first magnetic field source within a magnetic shield structure enclosing the vacuum chamber to generate a first supplemental magnetic field that reduces the magnitude of the vertical component of the residual magnetic field.

In Example 51, the subject matter of Example 50 includes, the operations further comprising: activating a second magnetic field source within the magnetic shield structure to generate a second supplemental magnetic field that reduces the magnitude of the horizontal component of the residual magnetic field.

In Example 52, the subject matter of Examples 50-51 includes, wherein the magnetic shield structure comprises a plurality of shield portions attached to a corresponding plurality of surfaces of the vacuum chamber.

Example 53 is at least one machine-readable medium including instructions that, when executed by processing circuitry, cause the processing circuitry to perform operations to implement any of Examples 1-52.

Example 54 is an apparatus comprising means to implement any of Examples 1-52.

Example 55 is a system to implement any of Examples 1-52.

Example 56 is a method to implement any of Examples 1-52.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components for example configurations may be implemented as a combined structure or component. Similarly, structures and functionality presented as a single component may be implemented as separate components. These and other variations, modifications, additions, and improvements fall within the scope of the subject matter herein.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

The claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in the context of specific illustrative configurations. Other allocations of functionality are envisioned and may fall within the scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

1. A semiconductor substrate processing apparatus, comprising:
a vacuum chamber including a processing zone for processing a substrate using capacitively coupled plasma (CCP);
a magnetic field sensor configured to detect a signal representing a residual magnetic field associated with the vacuum chamber;
at least one magnetic field source configured to generate one or more supplemental magnetic fields through the processing zone of the vacuum chamber; and
a magnetic field controller coupled to the magnetic field sensor and the at least one magnetic field source, the magnetic field controller configured to adjust at least one characteristic of the one or more supplemental magnetic fields, causing the one or more supplemental magnetic fields to reduce the residual magnetic field to a pre-determined value.

2. The apparatus of claim 1, wherein the magnetic field sensor is a wafer sensor placed within the processing zone of the vacuum chamber.

3. The apparatus of claim 2, wherein the wafer sensor comprises an array of magnetic field sensors configured to measure one or more parameters of the residual magnetic field at a plurality of locations within the processing zone; and
wherein the magnetic field controller adjusts the at least one characteristic of the one or more supplemental magnetic fields based on the measured one or more parameters.

4. The apparatus of claim 1, wherein the magnetic field sensor is configured to measure a magnitude of the residual magnetic field.

5. The apparatus of claim 4, wherein the at least one characteristic comprises a magnitude and a direction of the one or more supplemental magnetic fields.

6. The apparatus of claim 5, wherein the magnetic field controller is configured to:
set current through the at least one magnetic field source resulting in the magnitude of the one or more supplemental magnetic fields being equal to the magnitude of the residual magnetic field, and a direction of the one or more supplemental magnetic fields being opposite to a direction of the residual magnetic field.

7. The apparatus of claim 1, further comprising:
a magnetic shield structure configured to enclose the vacuum chamber; and
wherein the magnetic field sensor is one of:
mounted within the magnetic shield structure and outside of the vacuum chamber;
mounted outside of the magnetic shield structure; or
mounted within the vacuum chamber.

8. The apparatus of claim 7, wherein the at least one magnetic field source is a single-coil comprising a plurality of windings, and wherein the signal representing the residual magnetic field is detected within the magnetic shield structure and outside the vacuum chamber, or is detected within the vacuum chamber.

9. The apparatus of claim 8, wherein the single-coil is mounted within the magnetic shield structure and externally to the vacuum chamber.

10. The apparatus of claim 8, wherein the single-coil is mounted within the magnetic shield structure and internally to the vacuum chamber.

11. The apparatus of claim 7, wherein the at least one magnetic field source comprises a plurality of coils, each coil comprising a plurality of windings.

12. The apparatus of claim 11, wherein the plurality of coils are mounted within the magnetic shield structure and externally to the vacuum chamber.

13. The apparatus of claim 11, wherein the plurality of coils are mounted within the magnetic shield structure and internally to the vacuum chamber.

14. The apparatus of claim 11, wherein the plurality of coils includes a Helmholtz pair configured to generate at least one of the supplemental magnetic fields along a vertical axis or a horizontal axis of the vacuum chamber.

15. A method for processing a semiconductor substrate using a vacuum chamber, the method comprising:
detecting a residual magnetic field associated with a processing zone of the vacuum chamber, the processing zone for processing the semiconductor substrate using capacitively coupled plasma (CCP);
determining one or more parameters of the residual magnetic field; and
generating using at least one magnetic field source, one or more supplemental magnetic fields through the processing zone of the vacuum chamber based on the determined one or more parameters of the residual magnetic field.

16. The method of claim 15, wherein determining the one or more parameters further comprises:
determining a magnitude of a vertical component (Bz) of the residual magnetic field; and
determining a magnitude of a horizontal component (Bh) of the residual magnetic field.

17. The method of claim 16, further comprising:
activating a first magnetic field source of the at least one magnetic field source to generate a first supplemental magnetic field that reduces the magnitude of the vertical component of the residual magnetic field; and
activating a second magnetic field source of the at least one magnetic field source to generate a second supplemental magnetic field that reduces the magnitude of the horizontal component of the residual magnetic field.

18. The method of claim 15, further comprising:
providing a magnetic shield structure enclosing the vacuum chamber.

19. The method of claim 18, wherein the magnetic shield structure is configured to enclose the vacuum chamber, forming a plurality of air gaps between corresponding parallel surfaces of the vacuum chamber and the magnetic shield structure.

20. A machine-readable storage medium including instructions that, when executed by a machine, cause the machine to perform operations comprising:
detecting a residual magnetic field associated with a processing zone of a vacuum chamber, the processing zone for processing a semiconductor substrate using capacitively coupled plasma (CCP);
determining one or more parameters of the residual magnetic field; and
generating one or more supplemental magnetic fields through the processing zone of the vacuum chamber based on the determined one or more parameters of the residual magnetic field.

21. The machine-readable storage medium of claim 20, the operations further comprising:
determining a magnitude of a vertical component (Bz) of the residual magnetic field; and
determining a magnitude of a horizontal component (Bh) of the residual magnetic field.

22. The machine-readable storage medium of claim 21, the operations further comprising:
activating a first magnetic field source within a magnetic shield structure enclosing the vacuum chamber to generate a first supplemental magnetic field that reduces the magnitude of the vertical component of the residual magnetic field.

23. The machine-readable storage medium of claim 22, the operations further comprising:
activating a second magnetic field source within the magnetic shield structure to generate a second supplemental magnetic field that reduces the magnitude of the horizontal component of the residual magnetic field.

24. The machine-readable storage medium of claim 20, wherein the magnetic shield structure comprises a plurality of shield portions attached to a corresponding plurality of surfaces of the vacuum chamber.
